(19) United States
(12) Patent Application Publication
(10) Pub. No.: US 2026/0354185 A1
(43) Pub. Date: Nov. 5, 2026

(54) FLUIDIC DELIVERY PATH FOR MICROELECTRONICS COOLING

(71) Applicant: Raytheon Company, Arlington, VA (US)

(72) Inventors: Cynthia G. Sosa, Canyon Country, CA (US); Jason M. Kehl, Inglewood, CA (US); Jason G. Milne, El Segundo, CA (US); Aaron George, San Diego, CA (US); Dan Booth, Mckinney, TX (US)

(21) Appl. No.: 19/197,648

(22) Filed: May 2, 2025

(51) Int. Cl. H10W 40/47; H10W 70/65; H10W 70/66; H10W 70/68; H10W 74/15; H10W 90/00

(52) U.S. Cl. CPC H10W 40/47; H10W 70/65; H10W 70/66; H10W 70/68; H10W 74/15; H10W 90/724; H10W 90/726; H10W 90/734

(57) ABSTRACT

A cooling assembly for microelectronic devices addresses the challenge of efficiently dissipating heat from high-power components such as Application-Specific Integrated Circuits and Field-Programmable Gate Arrays. The assembly has a cooling manifold defining a portion of a fluid conduit, a substrate with electronic components, and solder rings creating a fluid path through the substrate. The fluid conduit forms a cooling loop through the substrate and into the high-power components, allowing fluid transmission to manage heat. The cooling manifold can function as a heat exchanger or connect to an external heat exchanger, enhancing cooling efficiency. The assembly's design integrates fluidic and electrical interconnects at the chip level, optimizing performance and reliability. The impermeable layer lining the solder rings ensures durability and effectiveness. This cooling assembly is particularly useful in environments with high power and pressure conditions, providing a robust solution for microelectronic cooling systems.

### TECHNICAL FIELD

Examples relate to cooling systems for electronics and more specifically to systems that cool electrical components in electrical systems.

### BACKGROUND

In the realm of microelectronics, efficient cooling of high-power components such as Application-Specific Integrated Circuits and Field-Programmable Gate Arrays is a persistent challenge. Traditional cooling methods, which typically involve the use of cold plates or heat sinks applied to the backside of circuit boards, often fail to adequately dissipate heat from the integrated circuits or silicon devices themselves. This limitation is particularly pronounced in environments where high power and pressure conditions prevail, necessitating more robust and effective cooling solutions.

Existing methods for integrating fluidic and electrical interconnects at the chip level are constrained by the need for large fasteners and connectors, which are not compatible with the scale of microelectronics. Furthermore, these approaches do not provide a seamless integration of electrical and fluidic inputs and outputs at the same surface, which is important for optimizing the performance and reliability of microelectronic devices. The absence of a method to directly cool heat-dissipating devices at the component level underscores the need for innovative solutions that can address these shortcomings and enhance the efficiency of microelectronic cooling systems.

### BRIEF DESCRIPTION OF DRAWINGS

FIGS. 1A and 1B illustrate an electronic component having a cooling assembly.

FIG. 2 is a cross-sectional view of the electronic component and the cooling assembly of FIGS. 1A and 1B.

FIG. 3 illustrates a cross-sectional view of a cooling manifold of the cooling assembly of FIG. 2.

FIG. 4 illustrates a cross-sectional view of a cooling manifold of the cooling assembly of FIG. 2 in accordance with a further example.

FIG. 5 is a cross-sectional view of the electronic component and a different cooling assembly that can be used with the electronic component of FIGS. 1A and 1B.

FIG. 6 is a cross-sectional view of the electronic component and a different cooling assembly that can be used with the electronic component of FIGS. 1A and 1B.

### DETAILED DESCRIPTION

The following description and the drawings sufficiently illustrate teachings to enable those skilled in the art to practice them. Other embodiments may incorporate structural, logical, electrical, process, and other changes. Portions and features of some examples may be included in, or substituted for, those of other examples. Teachings set forth in the claims encompass all available equivalents of those claims.

A cooling assembly for an electronic device is provided. The cooling assembly can provide a fluid conduit that extends from the electronic device to a cooling manifold. The cooling manifold can function to dissipate heat generated by the electronic device. The fluid conduit can pass completely through a substrate having components disposed thereon. Therefore, the fluid conduit can have a direct path to the cooling manifold. A first solder ring can be disposed between the cooling manifold and the substrate. Furthermore, a second solder ring can be disposed between the substrate and the electronic component. In addition, an impermeable metal can be disposed along the fluid conduit within the substrate.

The cooling manifold can function as a heat exchanger or provide heated fluid to an external heat exchanger. In examples where the cooling manifold functions as a heat exchanger, the fluid conduit can be a first cooling loop and the cooling manifold can have a second cooling loop. Cooling fluid in the second cooling loop can pull heat from heated fluid in the first cooling loop.

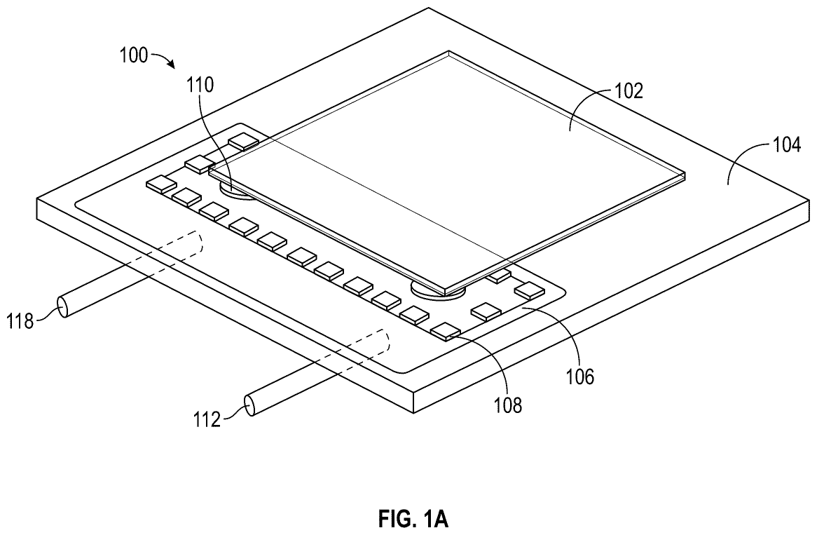

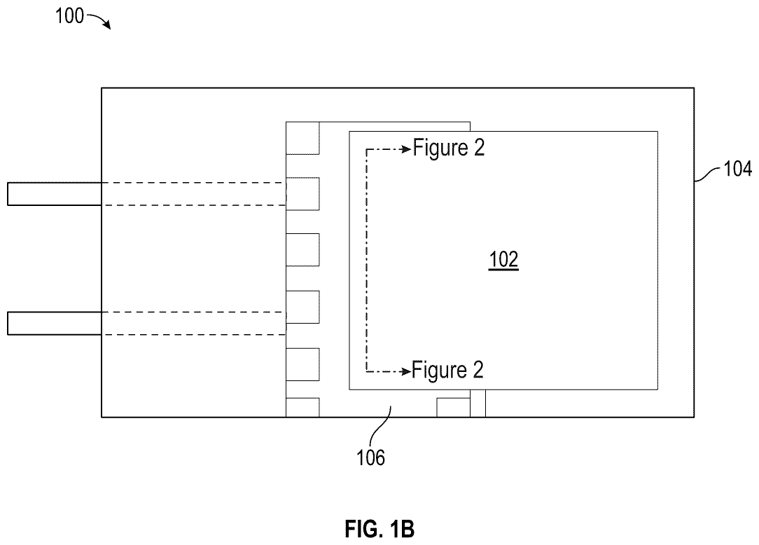

Now referring to FIGS. 1A and 1B, an electronic device 100, which implements a cooling assembly, is shown. The electronic device 100 can include a component 102 disposed on a substrate 104. The component 102 can be an Application-Specific Integrated Circuit, a Field-Programmable Gate Array, an oscillating heat pipe, a high-power processor, a silicon interposer, or any other type of electronic component. The substrate 104 can be organic, a printed circuit board, or any other type of structure on which componentry can be disposed. During operation, the component 102 can generate heat and therefore can be considered a heat generating device.

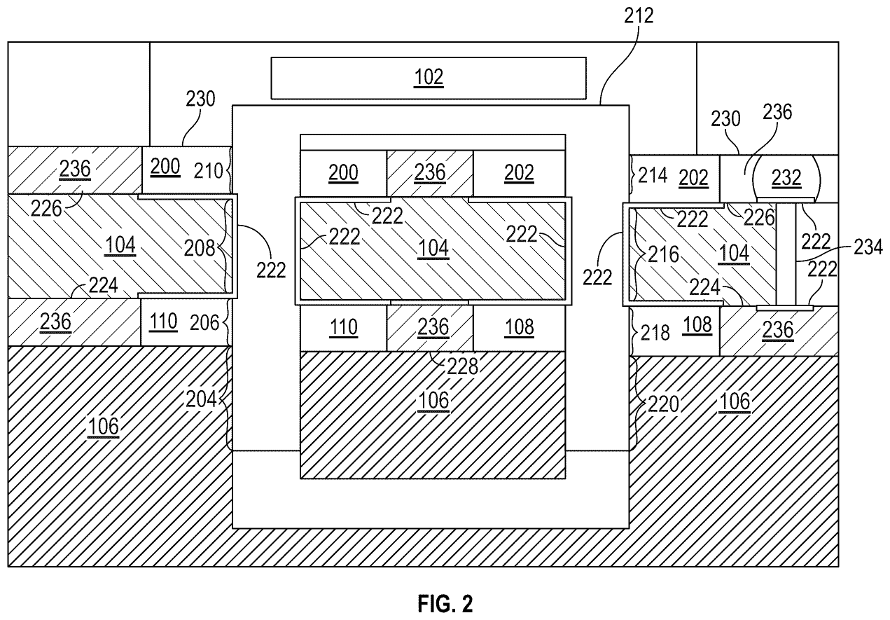

In order to provide thermal management for the component 102, the electronic device 100 can have a cooling manifold 106. The cooling manifold 106 can function to pull heat from the component 102. More specifically, making reference to FIG. 2, a cooling assembly can be formed in the electronic device 100 where heat can be removed from the component 102 via the cooling assembly. The cooling assembly can be formed by the substrate 104, the cooling manifold 106, and solder rings 108, 110, 200 and 202 where portions of the substrate 104, the cooling manifold 106, and the solder rings 108, 110, 200 and 202 can define a fluid conduit for the component 102. A heat transfer medium, such as a coolant, can traverse the fluid conduit in order to pull heat from the component 102.

The solder rings 108 and 110 can be between the substrate 104 and the cooling manifold 106. The solder rings 108 and 110 can be disposed on a top surface 228 of the cooling manifold 106. The solder rings 108 and 110 can also abut a bottom surface 224 of the substrate 104. The solder rings 200 and 202 can be between the substrate 104 and the component 102. The solder rings 200 and 202 can be disposed on a top surface 226 of the substrate 226. The solder rings 200 and 202 can also abut a bottom surface 230 of the component 102.

As shown with reference to FIG. 1A and the solder rings 108 and 110, the solder rings 108, 110, 200, and 202 can have a circular configuration where solder ring portions 206, 210, 214, and 218 are formed within the circular configuration. While a circular configuration is shown, the solder rings 108, 110, 200, and 202 can have any type of configuration, where the solder ring portions 206, 210, 214, and 218 are formed within the configuration. Moreover, the solder rings 108, 110, 200, and 202 can be formed from any type of alloy or mix of alloys. In addition, the solder rings 108, 110, 200, and 202 can be formed from epoxy such that the solder rings 108, 110, 200, and 202 can be epoxy rings.

A portion 204 of the cooling manifold 106 along with the portion 206 of the solder ring 110 can define the fluid conduit. Moreover, a portion 208 of the substrate 104 and the portion 210 of the solder ring 200 can define the fluid conduit. A portion of the component 102, such as a component fluid conduit 212, can also define the fluid conduit. The component fluid conduit 212 can also be referred to as a heat generating device fluid conduit.

In addition, the portion 214 of the solder ring 200 along with a portion 216 of the substrate 104 can define the fluid conduit. Furthermore, the portion 218 of the solder ring 108 along with a portion 220 of the cooling manifold 106 can define the fluid conduit. In examples, the portions 204-210 and 214-220 along with the component fluid conduit 212 can define a cooling loop within the cooling assembly. As can be seen with reference to FIG. 2, the substrate portions 208 and 216 of the fluid conduit can completely traverse the substrate. In particular, each of the substrate portions 208 and 216 can extend between the substrate bottom surface 224 and a top surface 226 of the substrate 104. Thus, the cooling loop can extend completely through the substrate 104.

During operation of the component 102, a coolant can be pumped through the cooling loop. The portions 204-210 and 214-220 along with the component fluid conduit 212 can be in fluid communication with each other. The cooling manifold portion 204 can be in fluid communication with the substrate portion 208 via the solder ring portion 206 where the solder ring portion 206 is in fluid communication with the cooling manifold portion 204 and the substrate portion 208. The component fluid conduit 212 can be in fluid communication with the substrate portion 216 via the solder ring portions 210 and 214 where the solder ring portion 210 is in fluid communication with the component fluid conduit 212 and the substrate portion 208 and the solder ring portion 214 is in fluid communication with the component fluid conduit 212 and the substrate portion 216.

The portions 204-210 and 214-220 along with the component fluid conduit 212 can be coupled with each other to allow the fluid flow of coolant through the cooling loop. The coolant can pull heat generated from the component 102. As will be discussed further on, heat exchange can then occur at the cooling manifold 106 where the heat absorbed from the component 102 by the coolant can be pulled from the coolant. Examples of coolant that can be used can include water, Ethanol, methanol, Ethylene glycol, Aliphatic (PAO), fluorocarbon (FC-77), liquid metal (GaIn, etc.), or the like.

In order to protect the substrate 104 from the coolant in the substrate portions 208 and 216, a wall of the substrate portions 208 and 216 can be lined with an impermeable layer 222, as shown with respect to FIG. 2. Thus, the impermeable layer 222 can line the substrate portions 208 and 216. The impermeable layer 222 can also be formed on the substrate bottom surface 224 where the solder rings 108 and 110 abut the substrate 104, as shown with reference to FIG. 2. Moreover, the impermeable layer 222 can be formed on the substrate top surface 226 where the solder rings 200 and 202 are disposed on the substrate 104, as shown with reference to FIG. 2. The impermeable layer 222 can be plated onto both sides of the substrate portions 208 and 216, at the substrate bottom surface 224 where the solder rings 108 and 110 abut the substrate 104, and at the substrate top surface 226 where the solder rings 200 and 202 are disposed on the substrate 104 substrate top surface 226 where the solder rings 200 and 202 are disposed on the substrate 104. The impermeable layer 222 can be formed from an impermeable material, such as copper, gold, or any other type of impermeable material.

The electronic device 100 can also include an electrical contact 232 that is electrically coupled with an electrical conduit 234. The electrical contact 232 can be a solder point that is disposed on the substrate top surface 226. The electrical contact 232 can extend between the substrate 104 and the component 102 and can provide an electrical contact to the component 102. The electrical conduit 234 can be disposed within the substrate 104 and extend completely through the substrate 104 from the substrate top surface 226 to the substrate bottom surface 224. The impermeable layer 222 can be located between the electrical contact 232 and the electrical conduit 234 at the substrate top surface 226. In addition, the impermeable layer 226 can be disposed at a bottom portion of the electrical conduit 234 at the substrate bottom surface 224, as shown with reference to FIG. 2.

The electrical contact 232 can be in a same plane as the solder rings 200 and 202. In particular, each of the solder rings 200 and 202 and the electrical contact 232 are formed on the substrate top surface 226, as shown with reference to FIG. 2. Moreover, the electrical contact 232 can be formed from the same materials as the solder contacts 200 and 202. By virtue of being in the same plane and being formed of the same materials, the solder rings 200 and 202 and the electrical contact 232 can be formed at the same time. Moreover, signals can be transmitted to and received from the component 102 via the electrical contact 232 and the electrical conduit 234. For example, signals relating to a temperature of the component 102 can be relayed via the electrical contact 232 and electrical conduit 234. When a temperature of the component 102 exceeds a threshold, a signal can be sent via the electrical contact 232 and the electrical conduit 234 indicating that cooling should commence via the cooling assembly to regulate the temperature of the component 102.

The electronic device 100 can also include underfill 236 disposed in the same planes as the solder rings 108, 110, 200, and 202. The underfill 236 can extend between the cooling manifold 106 and the substrate 104 where the underfill 236 can be disposed on the cooling manifold top surface 224 and extend to the substrate bottom surface 224. In addition, the underfill 236 can extend between the substrate 104 and the component 102 where the underfill 236 can be disposed on the substrate top surface 226 and extend to the component bottom surface 230. The underfill 236 can be formed from any non-conductive or inorganic material. The underfill 236 can provide structural and mechanical support for the component 102 and assist with allowing the component 102 to survive various cycles, such as thermal cycling, vibration, shock, and/or any other types of dynamic or static forces.

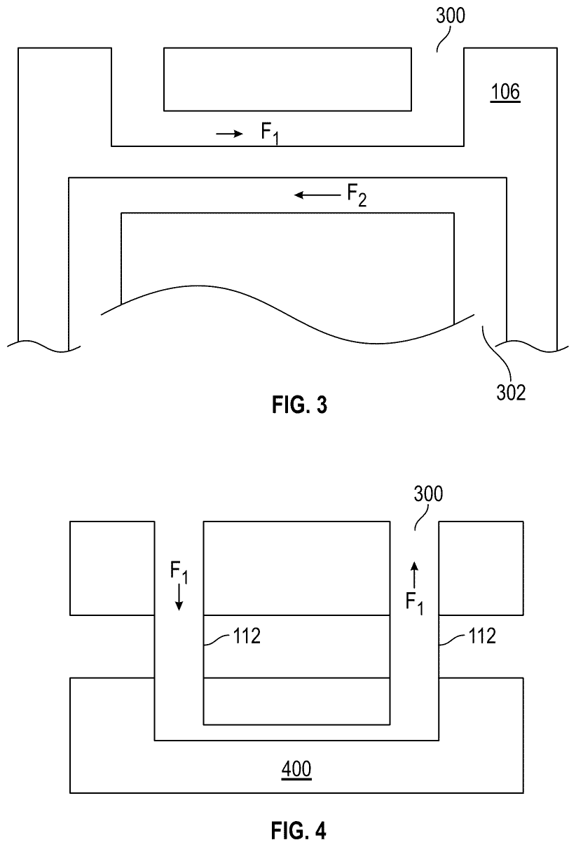

As noted above, the cooling manifold 106 can function to pull heat from the component 102. The cooling manifold 106 can include multiple cooling loops as shown with reference to FIG. 3. More specifically, the cooling manifold 106 can include a first cooling loop 300, which can correspond to the cooling loop described above with reference to FIG. 2, and a second cooling loop 302. The first cooling loop 300 can be a closed cooling loop that traverses the component 102, the substrate 104, the cooling manifold 106, and the solder rings 108,110, 200, and 202. The second cooling loop 302 can also be a closed cooling loop that is completely disposed within the cooling manifold 106. The coolant described with reference to FIG. 2 can be a first coolant F₁ in the first cooling loop 300 and a second coolant F₂ can be in the second cooling loop 302. The coolant F₁ and F₂ can travel in opposing directions in order to enhance heat transfer. The cooling manifold 106 can be formed from a material having high heat conductivity, such as a metal alloy that can include aluminum nitride, aluminum, tungsten, and graphene, along with copper. The second coolant F₂ can be the same material as the first coolant F₁ as described above. In examples, the second cooling loop 302 can be thermally coupled to a heat exchanger, such as radiative fins, where the cooling manifold 106 can include the radiative fins. Moreover, the cooling manifold can be exposed to ambient such that the cooling manifold 106 and the second coolant F₂ can radiate heat to ambient. Thus, the second cooling loop 302 can be configured to cool the cooling manifold 106. In further examples, the coolant F₂ could be pumped into the second cooling loop 302.

In further examples, the cooling manifold 106 can only include the first cooling loop 300. In this example, the cooling manifold can be thermally coupled with a heat exchanger 400, as shown with reference to FIG. 4. Here, the heat exchanger 400 can assist the cooling manifold 106 with pulling heat from the coolant F₁. In the example of the FIG. 4, the heat exchanger 400 can be any type of heat exchanger. Examples can include plate heat exchangers, brazed plate heat exchangers, micro-scale heat exchangers, dimple plate/plate coil heat exchangers, or plate-fin and tube-fin heat exchangers. While the cooling manifold 106 is shown as being in direct contact with the heat exchanger 400 in FIG. 4, in further examples, the cooling manifold 106 can include outlets/inlets 112 (FIG. 1) through which coolant can enter and exit the heat exchanger 400 where the cooling manifold 106 is spaced from the heat exchanger 400 via the outlets/inlets 112.

In additional examples, the cooling manifold 106 can only include the cooling loop 300 and function as a cold plate. Moreover, the cooling manifold can include a plate heat exchanger, as discussed above. In examples where the cooling manifold 106 only includes the single cooling loop 300, the coolant F₁ could be pumped into the cooling manifold 106 and then pumped out.

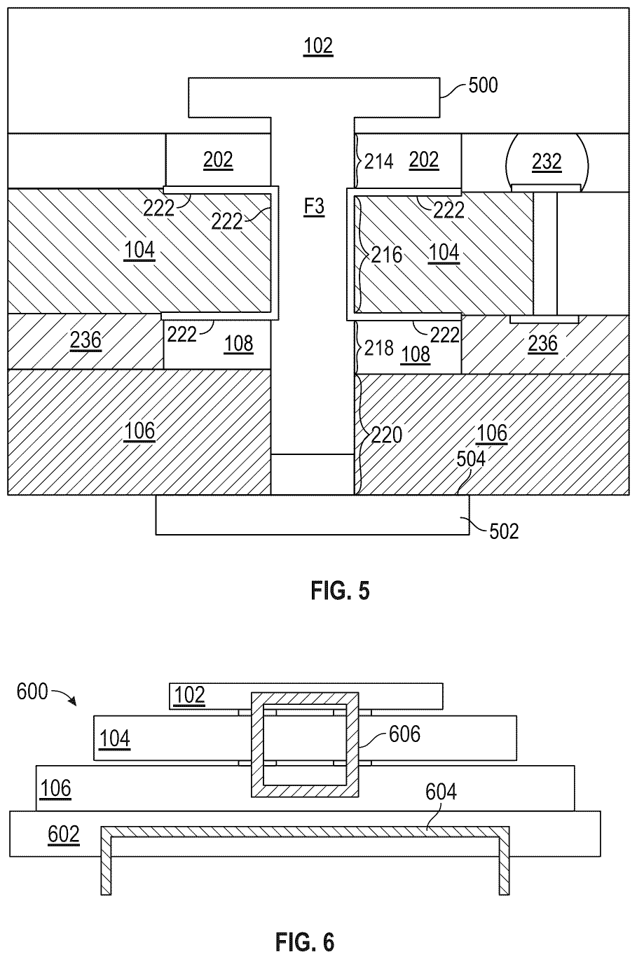

In the examples of FIGS. 3-5, the cooling assembly fluid conduit defines a cooling loop. In further examples, the cooling assembly can be part of a oscillating heat pipe where coolant within the cooling assembly does not circulate, as shown with respect to FIG. 5. Moreover, the coolant is not pumped into the cooling assembly, also as shown with reference to FIG. 5. In the example of FIG. 5, the cooling assembly can include the solder ring portions 214 and 218, the substrate portion 216, and the cooling manifold portion 220. Moreover, the component 102 can include an oscillating heat pipe 500, which, in combination with the solder ring portions 214 and 218, the substrate portion 216, and the cooling manifold portion 220, can form the cooling assembly in the example of FIG. 5. After formation of the cooling assembly, a fluid plug 502 can be used to close the cooling assembly. The fluid plug 500 can be disposed at a bottom surface 504 of the cooling manifold 106. The cooling manifold 106 can function to pull heat from coolant F₃, as described above. The fluid plug 500 can be formed from silicon, solder, epoxy, or any other type of the material that can form a fluid tight seal with the cooling manifold 106.

Now making reference to FIG. 6, a cross-sectional view of the electronic component and a different cooling assembly that can be used with the electronic component of FIGS. 1A and 1B is shown. Here, a cooling assembly 600 can include a heat exchanger 602 along with a first cooling loop 604 and a second cooling loop 606. The second cooling loop 606 can be a closed cooling loop that traverses the component 102, the substrate 104, the cooling manifold 106, and the solder rings 108,110, 200, and 202. The first cooling loop 604 can also be a closed cooling loop that is partially disposed within the heat exchanger 602. The second cooling loop can include the first coolant F₁ as described. Moreover, the first cooling loop 604 can include the second coolant F₂ as described above. The coolant F₁ and F₂ can travel in opposing directions in order to enhance heat transfer. The heat exchanger 602 can be formed from a material having high heat conductivity, such as a metal alloy that can include aluminum nitride, aluminum, tungsten, and graphene, along with copper. The second coolant F₂ can be the same material as the first coolant F₁ as described above. The heat exchanger 602 can include radiative fins. Moreover, the first cooling loop 604 can be exposed to ambient such that the second coolant F₂ can radiate heat to ambient. The first cooling loop 604 can also thermally couple with a second heat exchanger having a structure and functionality similar to the heat exchanger 602.

### Additional Examples

Example 1 is a cooling assembly for an electronic component, the cooling assembly comprising: a cooling manifold defining a cooling manifold portion of a fluid conduit; a substrate defining a substrate portion of the fluid conduit, wherein the substrate portion of the fluid conduit travels completely through the substrate and the cooling manifold portion is in fluid communication with the substrate portion; a first solder ring disposed between the cooling manifold and the substrate, the first solder ring defining a first solder ring portion of the fluid conduit, the first solder ring portion being in fluid communication with the cooling manifold portion and the substrate portion; an electronic component fluid conduit, the electronic component fluid conduit being in fluid communication with the substrate portion of the fluid conduit; a second solder ring disposed between the substrate and the electronic component, the second solder ring defining a second solder ring portion of the fluid conduit, the second solder ring portion being in fluid communication with the substrate portion and the electronic component fluid conduit, wherein: the substrate portion and each of the first solder ring and the second solder ring are lined with an impermeable layer; and the cooling manifold portion, the first solder ring portion, the substrate portion, the electronic component fluid conduit, and the second solder ring portion of the fluid conduit form a cooling loop configured to allow for transmission of fluid through the cooling assembly; an electrical conduit disposed within the substrate; and a solder point disposed between the substrate and the electronic component, the solder point forming an electrical contact between the electrical conduit and the electronic component.
In Example 2, the subject matter of Example 1 includes, wherein the cooling manifold is in fluid communication with a heat exchanger where the fluid in the cooling loop is cooled at the heat exchanger.
In Example 3, the subject matter of Examples 1-2 includes, wherein the cooling loop is a closed first cooling loop and the cooling manifold further includes a second cooling loop that is in fluid communication with a heat exchanger, the second cooling loop being configured to cool the cooling manifold.
In Example 4, the subject matter of Examples 1-3 includes, wherein the impermeable layer is one of gold or copper.
In Example 5, the subject matter of Examples 1-4 includes, a first under fill disposed between the cooling manifold and the substrate; and a second under fill disposed between the substrate and the electronic component.
In Example 6, the subject matter of Examples 1-5 includes, wherein the electronic component is one of an Application-Specific Integrated Circuit or a Field-Programmable Gate Array.
In Example 7, the subject matter of Examples 1-6 includes, wherein: a first portion of the impermeable layer is disposed between a bottom surface of the substrate and the first solder ring; and a second portion of the impermeable layer is disposed between a top surface of the substrate and the second solder ring.
Example 8 is a cooling assembly for an electronic component, the cooling assembly comprising: a cooling manifold defining a cooling manifold portion of a fluid conduit; a substrate defining a substrate portion of the fluid conduit, wherein the substrate portion of the fluid conduit travels completely through the substrate and the cooling manifold portion is in fluid communication with the substrate portion; a first solder ring disposed between the cooling manifold and the substrate, the first solder ring defining a first solder ring portion of the fluid conduit, the first solder ring portion being in fluid communication with the cooling manifold portion and the substrate portion; an electronic component fluid conduit, the electronic component fluid conduit being in fluid communication with the substrate portion of the fluid conduit; and a second solder ring disposed between the substrate and the electronic component, the second solder ring defining a second solder ring portion of the fluid conduit, the second solder ring portion being in fluid communication with the substrate portion and the electronic component fluid conduit, wherein: the substrate portion and each of the first solder ring and the second solder ring are lined with an impermeable layer; and the cooling manifold portion, the first solder ring portion, the substrate portion, the electronic component fluid conduit, and the second solder ring portion of the fluid conduit form a first cooling loop configured to allow for transmission of fluid through the cooling assembly and the cooling manifold further includes, a second cooling loop that is in fluid communication with a heat exchanger, the second cooling loop being configured to cool the cooling manifold.
In Example 9, the subject matter of Example 8 includes, wherein the impermeable layer is one of gold or copper.
In Example 10, the subject matter of Examples 8-9 includes, a first under fill disposed between the cooling manifold and the substrate; and a second under fill disposed between the substrate and the electronic component.
In Example 11, the subject matter of Examples 8-10 includes, wherein the electronic component is one of an Application-Specific Integrated Circuit or a Field-Programmable Gate Array.
In Example 12, the subject matter of Examples 8-11 includes, wherein: a first portion of the impermeable layer is disposed between a bottom surface of the substrate and the first solder ring; and a second portion of the impermeable layer is disposed between a top surface of the substrate and the second solder ring.
In Example 13, the subject matter of Examples 8-12 includes, an electrical conduit disposed within the substrate; and a solder point disposed between the substrate and the electronic component, the solder point forming an electrical contact between the electrical conduit and the electronic component.
Example 14 is a cooling assembly for an electronic component, the cooling assembly comprising: a cooling manifold defining a cooling manifold portion of a fluid conduit; a substrate defining a substrate portion of the fluid conduit, wherein the substrate portion of the fluid conduit travels completely through the substrate and the cooling manifold portion is in fluid communication with the substrate portion; a first solder ring disposed between the cooling manifold and the substrate, the first solder ring defining a first solder ring portion of the fluid conduit, the first solder ring portion being in fluid communication with the cooling manifold portion and the substrate portion; an electronic component fluid conduit, the electronic component fluid conduit being in fluid communication with the substrate portion of the fluid conduit; and a second solder ring disposed between the substrate and the electronic component, the second solder ring defining a second solder ring portion of the fluid conduit, the second solder ring portion being in fluid communication with the substrate portion and the electronic component fluid conduit, wherein: the substrate portion and each of the first solder ring and the second solder ring are lined with an impermeable layer; and the cooling manifold portion, the first solder ring portion, the substrate portion, the electronic component fluid conduit, and the second solder ring portion of the fluid conduit form a cooling loop configured to allow for transmission of fluid through the cooling assembly.
In Example 15, the subject matter of Example 14 includes, wherein the cooling manifold is in fluid communication with a heat exchanger where the fluid in the cooling loop is cooled at the heat exchanger.
In Example 16, the subject matter of Examples 14-15 includes, wherein the cooling loop is a closed first cooling loop and the cooling manifold further includes a second cooling loop that is in fluid communication with a heat exchanger, the second cooling loop being configured to cool the cooling manifold.
In Example 17, the subject matter of Examples 14-16 includes, wherein the impermeable layer is one of gold or copper.
In Example 18, the subject matter of Examples 14-17 includes, a first under fill disposed between the cooling manifold and the substrate; and a second under fill disposed between the substrate and the electronic component.
In Example 19, the subject matter of Examples 14-18 includes, wherein: a first portion of the impermeable layer is disposed between a bottom surface of the substrate and the first solder ring; and a second portion of the impermeable layer is disposed between a top surface of the substrate and the second solder ring.
In Example 20, the subject matter of Examples 14-19 includes, an electrical conduit disposed within the substrate; and a solder point disposed between the substrate and the electronic component, the solder point forming an electrical contact between the electrical conduit and the electronic component.
Example 21 is an apparatus comprising means to implement of any of Examples 1-20.
Example 22 is a system to implement of any of Examples 1-20.
Example 23 is a method to implement of any of Examples 1-20.

Although teachings have been described with reference to specific example teachings, it will be evident that various modifications and changes may be made to these teachings without departing from the broader spirit and scope of the teachings. Accordingly, the specification and drawings are to be regarded in an illustrative rather than a restrictive sense. The accompanying drawings that form a part hereof, show by way of illustration, and not of limitation, specific teachings in which the subject matter may be practiced. The teachings illustrated are described in sufficient detail to enable those skilled in the art to practice the teachings disclosed herein. Other teachings may be utilized and derived therefrom, such that structural and logical substitutions and changes may be made without departing from the scope of this disclosure. This Detailed Description, therefore, is not to be taken in a limiting sense, and the scope of various teachings is defined only by the appended claims, along with the full range of equivalents to which such claims are entitled.

What is claimed is:

1. A cooling assembly for an electronic component, the cooling assembly comprising:
a cooling manifold defining a cooling manifold portion of a fluid conduit;
a substrate defining a substrate portion of the fluid conduit, wherein the substrate portion of the fluid conduit travels completely through the substrate and the cooling manifold portion is in fluid communication with the substrate portion;
a first solder ring disposed between the cooling manifold and the substrate, the first solder ring defining a first solder ring portion of the fluid conduit, the first solder ring portion being in fluid communication with the cooling manifold portion and the substrate portion;
an electronic component fluid conduit, the electronic component fluid conduit being in fluid communication with the substrate portion of the fluid conduit;
a second solder ring disposed between the substrate and the electronic component, the second solder ring defining a second solder ring portion of the fluid conduit, the second solder ring portion being in fluid communication with the substrate portion and the electronic component fluid conduit, wherein:
the substrate portion and each of the first solder ring and the second solder ring are lined with an impermeable layer; and
the cooling manifold portion, the first solder ring portion, the substrate portion, the electronic component fluid conduit, and the second solder ring portion of the fluid conduit form a cooling loop configured to allow for transmission of a fluid through the cooling assembly;
an electrical conduit disposed within the substrate; and
a solder point disposed between the substrate and the electronic component, the solder point forming an electrical contact between the electrical conduit and the electronic component.

2. The cooling assembly of claim 1, wherein the cooling manifold is in fluid communication with a heat exchanger where the fluid in the cooling loop is cooled at the heat exchanger.

3. The cooling assembly of claim 1, wherein the cooling loop is a closed first cooling loop and the cooling manifold further includes a second cooling loop that is in fluid communication with a heat exchanger, the second cooling loop being configured to cool the cooling manifold.

4. The cooling assembly of claim 1, wherein the impermeable layer is one of gold or copper.

5. The cooling assembly of claim 1, further comprising:
a first under fill disposed between the cooling manifold and the substrate; and
a second under fill disposed between the substrate and the electronic component.

6. The cooling assembly of claim 1, wherein the electronic component is one of an Application-Specific Integrated Circuit or a Field-Programmable Gate Array.

7. The cooling assembly of claim 1, wherein:
a first portion of the impermeable layer is disposed between a bottom surface of the substrate and the first solder ring; and
a second portion of the impermeable layer is disposed between a top surface of the substrate and the second solder ring.

8. A cooling assembly for an electronic component, the cooling assembly comprising:
a cooling manifold defining a cooling manifold portion of a fluid conduit;
a substrate defining a substrate portion of the fluid conduit, wherein the substrate portion of the fluid conduit travels completely through the substrate and the cooling manifold portion is in fluid communication with the substrate portion;
a first solder ring disposed between the cooling manifold and the substrate, the first solder ring defining a first solder ring portion of the fluid conduit, the first solder ring portion being in fluid communication with the cooling manifold portion and the substrate portion;
an electronic component fluid conduit, the electronic component fluid conduit being in fluid communication with the substrate portion of the fluid conduit; and
a second solder ring disposed between the substrate and the electronic component, the second solder ring defining a second solder ring portion of the fluid conduit, the second solder ring portion being in fluid communication with the substrate portion and the electronic component fluid conduit, wherein:
the substrate portion and each of the first solder ring and the second solder ring are lined with an impermeable layer; and
the cooling manifold portion, the first solder ring portion, the substrate portion, the electronic component fluid conduit, and the second solder ring portion of the fluid conduit form a first cooling loop configured to allow for transmission of a fluid through the cooling assembly and the cooling manifold further includes a second cooling loop that is in fluid communication with a heat exchanger, the second cooling loop being configured to cool the cooling manifold.

9. The cooling assembly of claim 8, wherein the impermeable layer is one of gold or copper.

10. The cooling assembly of claim 8, further comprising:
a first under fill disposed between the cooling manifold and the substrate; and
a second under fill disposed between the substrate and the electronic component.

11. The cooling assembly of claim 8, wherein the electronic component is one of an Application-Specific Integrated Circuit or a Field-Programmable Gate Array.

12. The cooling assembly of claim 8, wherein:
a first portion of the impermeable layer is disposed between a bottom surface of the substrate and the first solder ring; and
a second portion of the impermeable layer is disposed between a top surface of the substrate and the second solder ring.

13. The cooling assembly of claim 8, further comprising:
an electrical conduit disposed within the substrate; and
a solder point disposed between the substrate and the electronic component, the solder point forming an electrical contact between the electrical conduit and the electronic component.

14. A cooling assembly for an electronic component, the cooling assembly comprising:
a cooling manifold defining a cooling manifold portion of a fluid conduit;
a substrate defining a substrate portion of the fluid conduit, wherein the substrate portion of the fluid conduit travels completely through the substrate and the cooling manifold portion is in fluid communication with the substrate portion;
a first solder ring disposed between the cooling manifold and the substrate, the first solder ring defining a first solder ring portion of the fluid conduit, the first solder ring portion being in fluid communication with the cooling manifold portion and the substrate portion;
an electronic component fluid conduit, the electronic component fluid conduit being in fluid communication with the substrate portion of the fluid conduit; and
a second solder ring disposed between the substrate and the electronic component, the second solder ring defining a second solder ring portion of the fluid conduit, the second solder ring portion being in fluid communication with the substrate portion and the electronic component fluid conduit, wherein:
the substrate portion and each of the first solder ring and the second solder ring are lined with an impermeable layer; and
the cooling manifold portion, the first solder ring portion, the substrate portion, the electronic component fluid conduit, and the second solder ring portion of the fluid conduit form a cooling loop configured to allow for transmission of a fluid through the cooling assembly.

15. The cooling assembly of claim 14, wherein the cooling manifold is in fluid communication with a heat exchanger where the fluid in the cooling loop is cooled at the heat exchanger.

16. The cooling assembly of claim 14, wherein the cooling loop is a closed first cooling loop and the cooling manifold further includes a second cooling loop that is in fluid communication with a heat exchanger, the second cooling loop being configured to cool the cooling manifold.

17. The cooling assembly of claim 14, wherein the impermeable layer is one of gold or copper.

18. The cooling assembly of claim 14, further comprising:
a first under fill disposed between the cooling manifold and the substrate; and
a second under fill disposed between the substrate and the electronic component.

19. The cooling assembly of claim 14, wherein:
a first portion of the impermeable layer is disposed between a bottom surface of the substrate and the first solder ring; and
a second portion of the impermeable layer is disposed between a top surface of the substrate and the second solder ring.

20. The cooling assembly of claim 14, further comprising:
an electrical conduit disposed within the substrate; and
a solder point disposed between the substrate and the electronic component, the solder point forming an electrical contact between the electrical conduit and the electronic component.
